(19) United States
(12) Patent Application Publication
(10) Pub. No.: US 2026/0129786 A1
(43) Pub. Date: May 7, 2026

(54) MULTIFUNCTIONAL RACK CABINET

(71) Applicant: DELTA ELECTRONICS, INC., Taoyuan City (TW)

(72) Inventors: Hsuan-Ting LIU, Taoyuan City (TW); Hsin-Yu SU, Taoyuan City (TW); Shao-Shun CHIU, Taoyuan City (TW); Sheng-Zhi ZHANG, Taoyuan City (TW); Ren-Chun CHANG, Taoyuan City (TW)

(21) Appl. No.: 19/351,278

(22) Filed: Oct. 6, 2025

(30) Foreign Application Priority Data
Nov. 6, 2024 (CN) 202411572860.2

(51) Int. Cl. H05K 7/14

(52) U.S. Cl. CPC H05K 7/1492

(57) ABSTRACT

A multifunctional rack cabinet includes a support rack, an outer door, an electric control box, a first inner door, and a second inner door. The outer door is pivotally connected to an edge of the support rack. The electric control box is connected to the support rack and includes a main switch, at least one control unit, at least one pump switch, at least one sensor interface, and plural electrical components. The first inner door is pivotally connected to an edge of the electric control box and covers the control unit, the pump switch, and the sensor interface, wherein the main switch is at least partially exposed through the first inner door. The second inner door covers the electrical components. The main switch, the control unit, the pump switch, and the sensor interface are at least partially exposed through the second inner door.

### CROSS-REFERENCE TO RELATED APPLICATION

This application claims priority to China Application Serial Number 202411572860.2, filed Nov. 6, 2024, which is herein incorporated by reference.

### BACKGROUND

### Field of Invention

The present disclosure relates to a multifunctional rack cabinet, especially relates to a multifunctional rack cabinet having plural doors.

### Description of Related Art

Since the cooling system in a data center is very important, cabinet designs used for the cooling system also tend to be diverse. For example, a cabinet can accommodate an electric control box and various electronic components for protection. The data center stores and transmits important information. In order to prevent unauthorized persons from easily opening and closing the door of the cabinet, a lock can be used to prevent theft. However, it is difficult for operators and technicians of different levels to identify their identities. For example, the operators may operate electronic components that only the technicians have access to, thereby causing the system and machines in the cabinet to fail to operate normally.

### SUMMARY

According to some embodiments of the present disclosure, a multifunctional rack cabinet includes a support rack, an outer door, an electric control box, a first inner door, and a second inner door. The outer door is pivotally connected to an edge of the support rack. The electric control box is connected to the support rack and includes a main switch, at least one control unit, at least one pump switch, at least one sensor interface, and plural electrical components. The first inner door is pivotally connected to an edge of the electric control box and covers the control unit, the pump switch, and the sensor interface, wherein the main switch is at least partially exposed through the first inner door. The second inner door is pivotally connected to the edge of the electric control box and covers the electrical components. The first inner door is located between the outer door and the second inner door, and the main switch, the control unit, the pump switch, and the sensor interface are at least partially exposed through the second inner door.

In some embodiments, the first inner door further includes an opening, and a position of the opening corresponds to a position of the main switch.

In some embodiments, the main switch includes a switching element and a handle. One end of the handle is located above the switching element, and the handle extends to a position below the switching element and is configured to block or allow the switching element to move along a horizontal direction. The switching element and the handle are exposed through the opening of the first inner door.

In some embodiments, the multifunctional rack cabinet further includes a lock hung on the handle of the main switch and located outside the first inner door.

In some embodiments, the first inner door further includes a keyhole configured to be unlocked with a key to open the first inner door.

In some embodiments, a corner of the second inner door has a notch, and a position of the notch corresponds to a position of the control unit.

In some embodiments, a corner of the second inner door has a notch, and a position of the notch corresponds to a position of the sensor interface.

In some embodiments, the second inner door has an opening, and a position of the opening corresponds to a position of the main switch.

In some embodiments, the second inner door has an opening, and a position of the opening corresponds to a position of the pump switch.

In some embodiments, the multifunctional rack cabinet further includes at least one pump located on the support rack and below the electric control box, and electrically connected to the pump switch.

In some embodiments, the control unit includes a variable-frequency drive.

In some embodiments, the electrical components include a control circuit switch and a power line.

In some embodiments, a height of the outer door is greater than a height of the first inner door and a height of the second inner door.

In some embodiments, an area of the first inner door is greater than an area of the second inner door.

In some embodiments, the multifunctional rack cabinet further includes a display device located on the outer door.

In some embodiments, the multifunctional rack cabinet further includes a rear door pivotally connected to a side of the support rack facing away from the outer door.

According to some embodiments of the present disclosure, a multifunctional rack cabinet includes an outer door, an electric control box, a first inner door, and a second inner door. The electric control box includes a main switch, at least one control unit, at least one pump switch, at least one sensor interface, and plural electrical components. The first inner door is pivotally connected to an edge of the electric control box and covers the control unit, the pump switch, and the sensor interface, wherein the first inner door further includes an opening, and a position of the opening corresponds to a position of the main switch, such that the main switch is at least partially exposed through the first inner door. The second inner door is pivotally connected to the edge of the electric control box and covers the electrical components. The first inner door is located between the outer door and the second inner door, and the main switch, the control unit, the pump switch, and the sensor interface are at least partially exposed through the second inner door.

In some embodiments, the main switch includes a switching element and a handle. One end of the handle is located above the switching element, and the handle extends to a position below the switching element and is configured to block or allow the switching element to move along a horizontal direction. The switching element and the handle are exposed through the opening of the first inner door.

In some embodiments, the multifunctional rack cabinet further includes a lock hung on the handle of the main switch and located outside the first inner door.

In some embodiments, the first inner door further includes a keyhole configured to be unlocked with a key to open the first inner door.

In the aforementioned embodiments of the present disclosure, since the multifunctional rack cabinet includes the outer door, the electric control box, the first inner door and the second inner door, and the first inner door is located between the outer door and the second inner door, the first inner door can cover the control unit, the pump switch, and the sensor interface of the electric control box, the main switch can be at least partially exposed through the first inner door, the second inner door can cover the electrical components, and the main switch, the control unit, the pump switch, and the sensor interface can be at least partially exposed through the second inner door. As a result, the multifunctional rack cabinet is capable of anti-theft and anti-accidental touch to achieve hierarchical control of personnel. For example, the outer door can prevent unauthorized persons from opening and closing, and the first inner door may allow an operator to start and switch electricity in safe and simple operations by utilizing the main switch. Moreover, the first inner door can prevent the operator from touching electronic components that only technicians have access to, and the second inner door can prevent non-electrical maintenance personnel from touching the electrical components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a multifunctional rack cabinet according to one embodiment of the present disclosure.

FIG. 2 is a partially enlarged view of a first inner door of FIG. 1.

FIG. 3 is a partially enlarged view of a main switch of FIG. 2.

FIG. 4 is a perspective view of the multifunctional rack cabinet of FIG. 1 when the first inner door is opened.

FIG. 5 is a partially enlarged view of an electric control box of FIG. 4.

FIG. 6 is a perspective view of the multifunctional rack cabinet of FIG. 5 when the second inner door is opened.

FIG. 7 is a partially enlarged view of the electric control box of FIG. 6.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

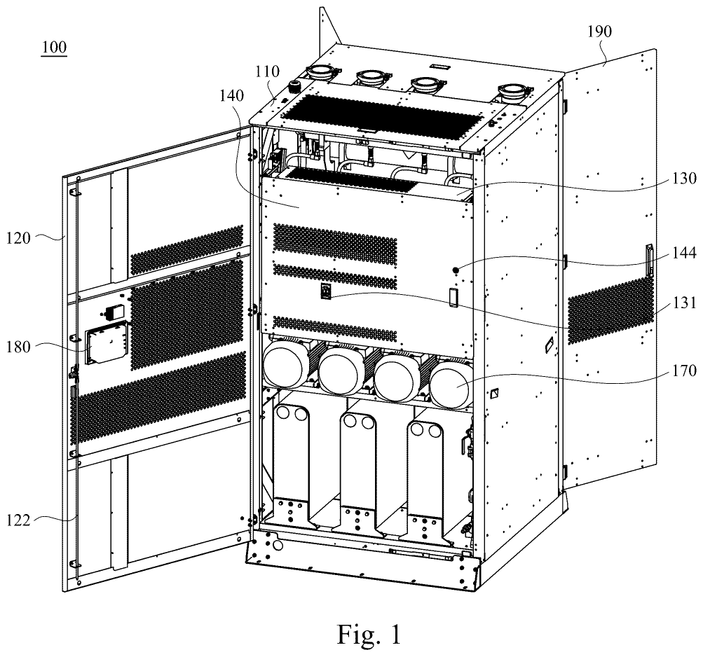

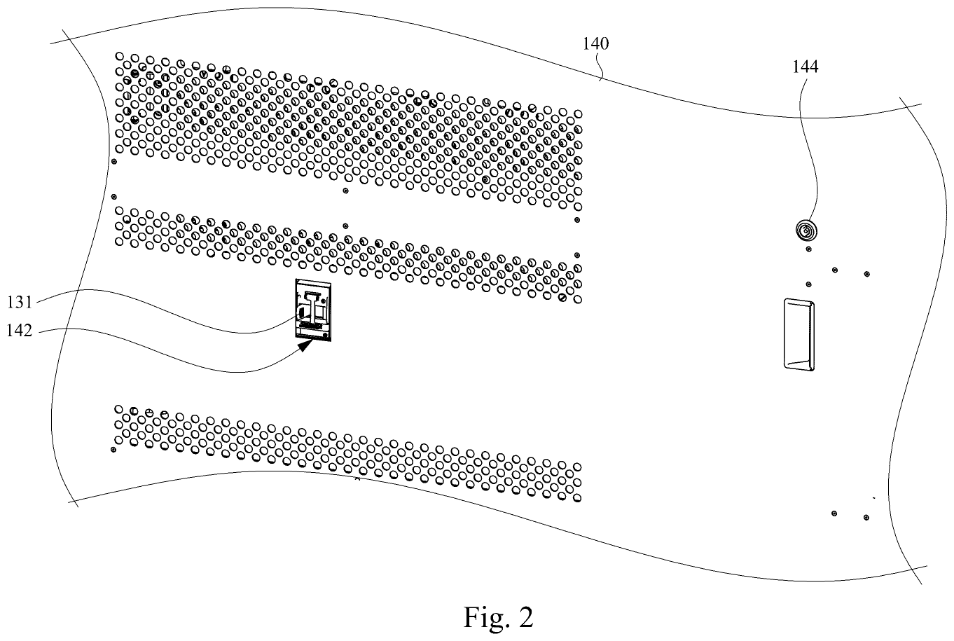

FIG. 1 is a perspective view of a multifunctional rack cabinet 100 according to one embodiment of the present disclosure. FIG. 2 is a partially enlarged view of a first inner door 140 of FIG. 1. As shown in FIG. 1 and FIG. 2, the multifunctional rack cabinet 100 includes a support rack 110, an outer door 120, an electric control box 130, and the first inner door 140. The outer door 120 is pivotally connected to an edge (e.g., a left edge) of the support rack 110. The electric control box 130 is connected to the support rack 110 and includes a main switch 131. The first inner door 140 is pivotally connected to an edge (e.g., a left edge) of the electric control box 130. The main switch 131 is at least partially exposed through the first inner door 140. In this embodiment, the first inner door 140 has an opening 142, and the position of the opening 142 corresponds to the position of the main switch 131, such that the main switch 131 can be at least partially exposed through the first inner door 140. Because the main switch 131 exposes the main switch 131, an operator can start and switch power in safe and simple operations.

In some embodiments, the multifunctional rack cabinet 100 may be used in a cooling system (a water cooling system) of a data center, but the present disclosure is not limited in this regard. The multifunctional rack cabinet 100 further includes a display device 180. The display device 180 is located on the outer door 120. When the outer door 120 is closed, the display device 180 faces outward and display a system running status. In addition, the outer door 120 has a heaven and earth lock 122. When the outer door 120 is closed, the outer door 120 is locked by the heaven and earth lock 122. When the outer door 120 is opened, the display device 180 may generate warnings.

In some embodiments, the outer door 120 merely allows operators to open, but the first inner door 140 cannot be opened by the operators, and can only be opened by technicians. Through the aforementioned configuration, unauthorized persons cannot open and close the outer door 120, thereby preventing persons other than operators and technicians (such as visitors) from entering the multifunctional rack cabinet 100 to cause systems and machines to operate abnormally. In this embodiment, the first inner door 140 further includes a keyhole 144 configured to be unlocked with a key to open the first inner door 140, such that only technicians having the key can open the first inner door 140, thereby achieving the effect of hierarchical management of personnel.

In addition to the outer door 120 and the first inner door 140 that are capable of anti-theft and anti-accidental touch to achieve hierarchical control of personnel, the first inner door 140 exposes the main switch 131 on the outermost layer of the electric control box 130 (e.g., an electrical panel), which can directly control the operation of the entire system (e.g., power supply and switch off) after opening the outer door 120.

In this embodiment, the multifunctional rack cabinet 100 further includes a rear door 190 and at least one pump 170. The rear door 190 is pivotally connected to a side (e.g., a back side) of the support rack 110 facing away from the outer door 120, and a space in the rear door 190 may accommodate cooling pipelines. The pump 170 is located on the support rack 110 and below the electric control box 130. The pump 170 is electrically connected to the electric control box 130, and is fluidly connected to the cooling pipelines. When a water circuit is abnormal, an operator may open the rear door 190 to confirm the operating status of the water circuit.

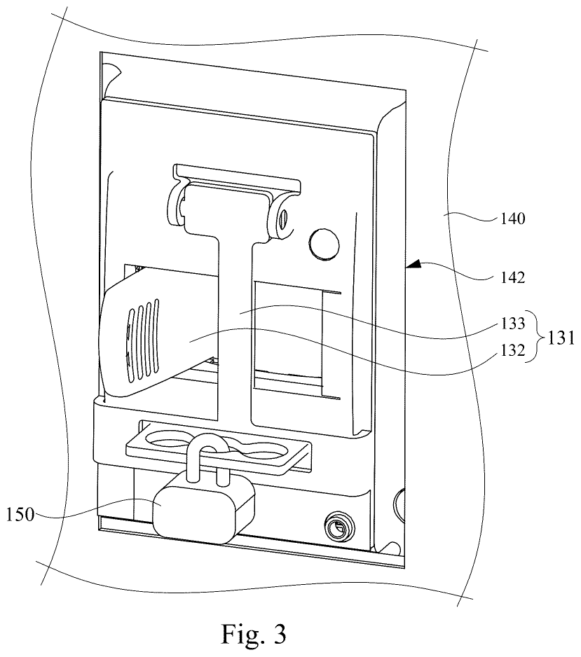

FIG. 3 is a partially enlarged view of the main switch 131 of FIG. 2. As shown in FIG. 2 and FIG. 3, the main switch 131 includes a switching element 132 and a handle 133. One end of the handle 133 is located above the switching element 132, and the handle 133 extends to a position below the switching element 132 and is configured to block or allow the switching element 132 to move along a horizontal direction. Furthermore, the switching element 132 and the handle 133 are exposed through the opening 142 of the first inner door 140. Moreover, a lock 150 may be optionally hung on the handle 133 of the main switch 131, and the lock 150 is located outside the first inner door 140. When the main switch 131 trips, an operator may unlock the lock 150, and then may pull the handle 133 from bottom to top. Thereafter, the switching element 132 can be turned to the right and then to the left to restore power. The lock 150 and the keyhole 144 of the first inner door 140 are not only capable of anti-theft, but also can prevent the operator from touching other electronic components (e.g., charged components and inductive components) in the first inner door 140. The operator can control the operation of the entire system by the main switch 131 after opening the support rack 110, such as starting and shutting down the system. The water cooling system is one of the main equipment of the data center for cooling a high temperature caused by a power system, and thus conditions for accidental contact must be minimized, so the lock 150 is hung to be artificially impossible to pull the main switch 131 by hand to disconnect. The cooling system needs to be in place at all times to prevent the possibility of serious damage to the equipment caused by accidental touch.

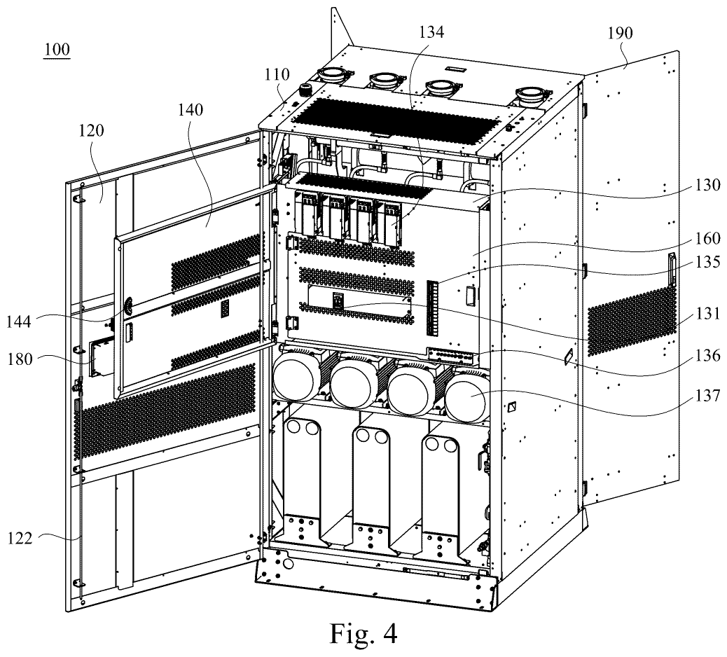

FIG. 4 is a perspective view of the multifunctional rack cabinet 100 of FIG. 1 when the first inner door 140 is opened. As shown in FIG. 1 and FIG. 4, the multifunctional rack cabinet 100 further includes a second inner door 160. The electric control box 130 further includes at least one control unit 134, at least one pump switch 135, and at least one sensor interface 136. The present disclosure is not limited to the number of the control units 134, the number of the pump switches 135, and the number of the sensor interfaces 136. The control unit may include a variable-frequency drive (VFD). The pump switch 135 is electrically connected to the pump 170. When the first inner door 140 is closed (shown in FIG. 1), the first inner door 140 covers the control unit 134, the pump switch 135, and the sensor interface 136. The second inner door 160 is pivotally connected to the edge (e.g., a left edge) of the electric control box 130. When the first inner door 140 is opened and the second inner door 160 is closed (as shown in FIG. 4), the main switch 131, the control unit 134, the pump switch 135, and the sensor interface 136 are at least partially exposed through the second inner door 160.

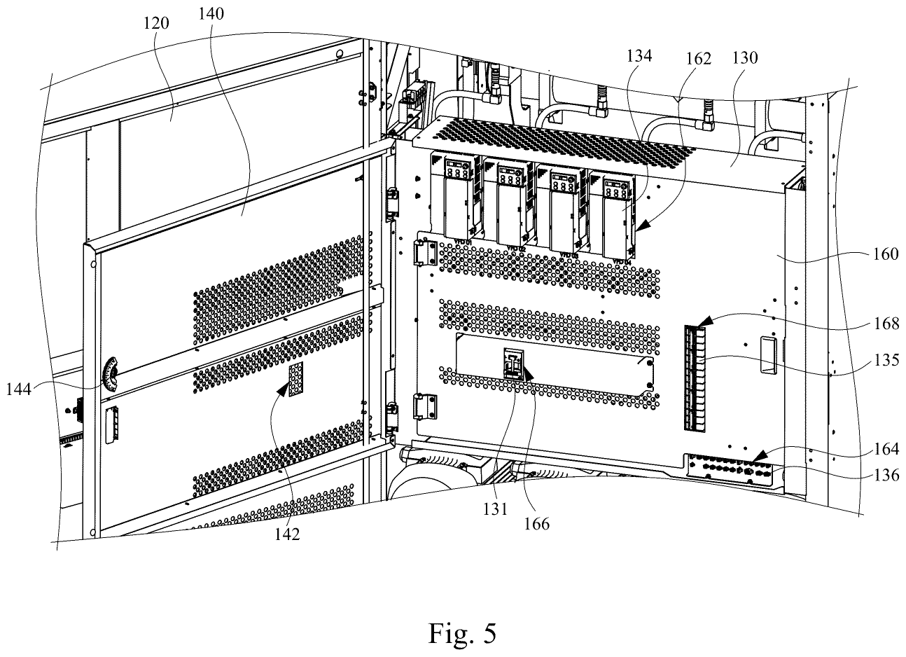

FIG. 5 is a partially enlarged view of the electric control box 130 of FIG. 4. As shown in FIG. 4 and FIG. 5, two corners of the second inner door 160 respectively have a notch 162 and a notch 164, the position of the notch 162 corresponds to the position of the control unit 134, and the position of the notch 164 corresponds to the position of the sensor interface 136. In such a design, the control unit 134 may be exposed through the notch 162 of the second inner door 160, and the sensor interface 136 may be exposed through the notch 164 of the second inner door 160. Technicians can observe and repair the control unit 134 and the sensor interface 136 respectively through the notch 162 and the notch 164 when the second inner door 160 is closed. In addition, the second inner door 160 has an opening 166 and an opening 168, the position of the opening 166 corresponds to the position of the main switch 131, and the position of the opening 168 corresponds to the position of the pump switch 135. As a result of such a design, the second inner door 160 can expose the control unit 134, the sensor interface 136, the main switch 131, and the pump switch 135.

When the second inner door 160 is closed, the second inner door 160 may allow technicians (e.g., inspection personnel) to turn on and off the component switch of each of circuits, such as using the pump switch 135 to control the operation of the corresponding pump 170. Since the pump 170 is a consumable component and each pump switch 135 can be independently switched off without opening the second inner door 160, technicians can perform maintenance and component replacement on the pump 170 without shutting down the system. Alternatively, the technicians can know that a sensing element is abnormal through the exposed sensor interface 136, and may also perform repair and replacement. The second inner door 160 may allow the technicians (e.g., inspection personnel) to confirm whether the status of important components (e.g., the pump 170) is good, and to confirm the opening and closing of the circuit of each important component to control the operation of each important component (e.g., each pump 170).

Although the second inner door 160 of the multifunctional rack cabinet 100 exposes the switches and components of important control circuits, the layout of power lines is shielded. The closed second inner door 160 can prevent non-electrical maintenance personnel from touching electronic components in the second inner door 160.

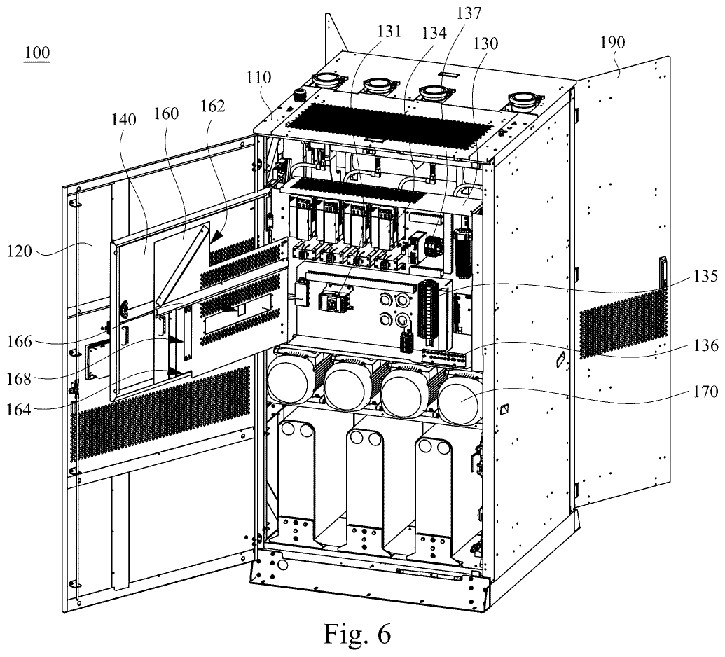

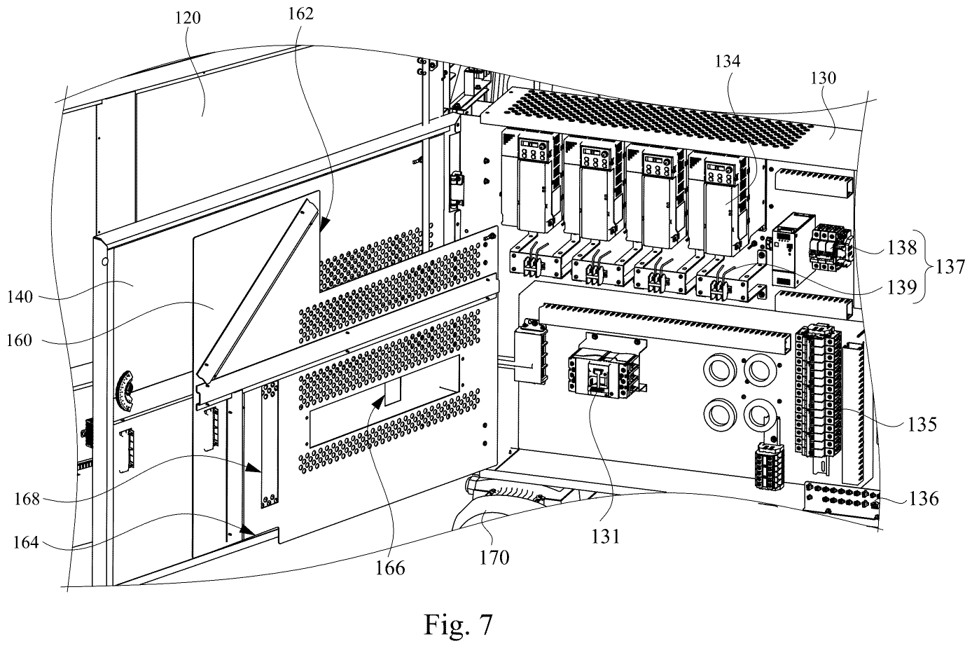

FIG. 6 is a perspective view of the multifunctional rack cabinet 100 of FIG. 5 when the second inner door 160 is opened. FIG. 7 is a partially enlarged view of the electric control box 130 of FIG. 6. As shown in FIG. 6 and FIG. 7, the first inner door 140 is located between the outer door 120 and the second inner door 160. The height of the outer door 120 is greater than the height of the first inner door 140 and the height of the second inner door 160, and the area of the first inner door 140 is greater than the area of the second inner door 160. The electric control box 130 includes plural electrical components 137, and the electrical components 137 can be covered by the closed second inner door 160 (as shown in FIG. 5). In some embodiments, the electrical components 137 may include a control circuit switch 138 and a power line 139, but the present disclosure is not limited in this regard.

When the second inner door 160 is opened, main power needs to be switched off from main switch 131, and repairs are done by electrical maintenance personnel to perform comprehensive maintenance and replacement. For example, the design of the second inner door 160 may be used for disposing equipment during initial installation, or used for performing maintenance of electricity in the state of serious abnormality of this system. Only after the second inner door 160 is opened, the electrical maintenance personnel can replace protective components (e.g., the control circuit switch 138) and control components (e.g., the control unit 134).

In summary, the multifunctional rack cabinet 100 combines the advantages of maintenance and control. Since the multifunctional rack cabinet 100 includes the outer door 120, the electric control box 130, the first inner door 140 and the second inner door 160, and the first inner door 140 is located between the outer door 120 and the second inner door 160, the first inner door 140 (see FIG. 1) can cover the control unit 134, the pump switch 135, and the sensor interface 136 of the electric control box 130, the main switch 131 can be at least partially exposed through the first inner door 140, the second inner door 160 (see FIG. 4) can cover the electrical components 137, and the main switch 131, the control unit 134, the pump switch 135, and the sensor interface 136 can be at least partially exposed through the second inner door 160. As a result, the multifunctional rack cabinet 100 is capable of anti-theft and anti-accidental touch to achieve hierarchical control of personnel. For example, the outer door 120 can prevent unauthorized persons from opening and closing, and the first inner door 140 may allow an operator to start and switch electricity by utilizing the main switch 131 in safe and simple operation. Moreover, the first inner door 140 can prevent the operator from touching electronic components that only technicians have access to, and the second inner door can prevent non-electrical maintenance personnel from touching the electrical component 137.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A multifunctional rack cabinet, comprising:
a support rack;
an outer door pivotally connected to an edge of the support rack;
an electric control box connected to the support rack and comprising a main switch, at least one control unit, at least one pump switch, at least one sensor interface, and a plurality of electrical components;
a first inner door pivotally connected to an edge of the electric control box and covering the control unit, the pump switch, and the sensor interface, wherein the main switch is at least partially exposed through the first inner door; and
a second inner door pivotally connected to the edge of the electric control box and covering the electrical components, wherein the first inner door is located between the outer door and the second inner door, and the main switch, the control unit, the pump switch, and the sensor interface are at least partially exposed through the second inner door.

2. The multifunctional rack cabinet of claim 1, wherein the first inner door further comprises an opening, and a position of the opening corresponds to a position of the main switch.

3. The multifunctional rack cabinet of claim 2, wherein the main switch comprises:
a switching element; and
a handle, wherein one end of the handle is located above the switching element, and the handle extends to a position below the switching element and is configured to block or allow the switching element to move along a horizontal direction;
wherein the switching element and the handle are exposed through the opening of the first inner door.

4. The multifunctional rack cabinet of claim 3, further comprising:
a lock hung on the handle of the main switch and located outside the first inner door.

5. The multifunctional rack cabinet of claim 1, wherein the first inner door further comprises a keyhole configured to be unlocked with a key to open the first inner door.

6. The multifunctional rack cabinet of claim 1, wherein a corner of the second inner door has a notch, and a position of the notch corresponds to a position of the control unit.

7. The multifunctional rack cabinet of claim 1, wherein a corner of the second inner door has a notch, and a position of the notch corresponds to a position of the sensor interface.

8. The multifunctional rack cabinet of claim 1, wherein the second inner door has an opening, and a position of the opening corresponds to a position of the main switch.

9. The multifunctional rack cabinet of claim 1, wherein the second inner door has an opening, and a position of the opening corresponds to a position of the pump switch.

10. The multifunctional rack cabinet of claim 1, further comprising:
at least one pump located on the support rack and below the electric control box, and electrically connected to the pump switch.

11. The multifunctional rack cabinet of claim 1, wherein the control unit comprises a variable-frequency drive.

12. The multifunctional rack cabinet of claim 1, wherein the electrical components comprise a control circuit switch and a power line.

13. The multifunctional rack cabinet of claim 1, wherein a height of the outer door is greater than a height of the first inner door and a height of the second inner door.

14. The multifunctional rack cabinet of claim 1, wherein an area of the first inner door is greater than an area of the second inner door.

15. The multifunctional rack cabinet of claim 1, further comprising:
a display device located on the outer door.

16. The multifunctional rack cabinet of claim 1, further comprising:
a rear door pivotally connected to a side of the support rack facing away from the outer door.

17. A multifunctional rack cabinet, comprising:
an outer door;
an electric control box comprising a main switch, at least one control unit, at least one pump switch, at least one sensor interface, and a plurality of electrical components;
a first inner door pivotally connected to an edge of the electric control box and covering the control unit, the pump switch, and the sensor interface, wherein the first inner door further comprises an opening, and a position of the opening corresponds to a position of the main switch, such that the main switch is at least partially exposed through the first inner door; and
a second inner door pivotally connected to the edge of the electric control box and covering the electrical components, wherein the first inner door is located between the outer door and the second inner door, and the main switch, the control unit, the pump switch, and the sensor interface are at least partially exposed through the second inner door.

18. The multifunctional rack cabinet of claim 17, wherein the main switch comprises:
a switching element; and
a handle, wherein one end of the handle is located above the switching element, and the handle extends to a position below the switching element and is configured to block or allow the switching element to move along a horizontal direction;
wherein the switching element and the handle are exposed through the opening of the first inner door.

19. The multifunctional rack cabinet of claim 18, further comprising:
a lock hung on the handle of the main switch and located outside the first inner door.

20. The multifunctional rack cabinet of claim 17, wherein the first inner door further comprises a keyhole configured to be unlocked with a key to open the first inner door.
